(19) United States
(12) Patent Application Publication
(10) Pub. No.: US 2007/0269915 A1
(43) Pub. Date: Nov. 22, 2007

(54) LED devices incorporating moisture-resistant seals and having ceramic substrates

(76) Inventors: Ak Wing Leong, Penang (MY); Kee Yean Ng, Penang (MY); Tajul Arosh Baroky, Penang (MY)

Correspondence Address: Kathy Manke;Avago Technologies Limited, 4380 Ziegler Road, Fort Collins, CO, 80525, US

(21) Appl. No.: 11/435,450

(22) Filed: May 16, 2006

(51) Int. Cl. H01L 21/00

(52) U.S. Cl. 438/28

(57) ABSTRACT

A New Moisture-Resistant LED Device with Ceramic Substrate is disclosed. The Moisture-Resistant LED Device with Ceramic Substrate includes a ceramic substrate having a concave cavity, a light emitting diode (“LED”) in the concave cavity, a filler body over the LED, and a window sealed at an interface with the ceramic substrate.

### BACKGROUND OF THE INVENTION

Light emitting diode (“LED”) devices are useful for generating light output. LED devices may convert electricity into photonic emissions in the form of visible light more efficiently than incandescent and fluorescent bulbs, and may be individually fabricated to generate light emissions at any of a variety of pre-selected wavelengths or wavelength bands. An LED may be positioned in a concave base housing adapted to provide an initial focus for the light output from the LED. The LED may be provided with anode and cathode bonding wires communicating with conductive leads that place the LED in communication with an electrical circuit for supplying a bias voltage to the LED. The LED may be encapsulated in a material intended to protect the LED from external contaminants and from being physically damaged or dislodged, and to form part of a lens system for further focusing the light output of the LED. Epoxy resins are often selected as the encapsulant, due to their material properties including hardness, resistance to chemicals, good adhesion to diverse materials, and good optical properties. Moisture-resistant epoxy resins are commonly used as the encapsulant, in order to further protect the LED device from degradation.

Despite typical design features of LED devices including those summarized above, LED devices are commonly prone to variable damage from external contaminants such as moisture. The optical grade encapsulant materials commonly used to package LEDs into operable LED devices typically absorb some moisture. This absorption occurs to some extent even when moisture-resistant epoxy encapsulants are used. Encapsulant additives such as phosphors may also absorb moisture. Phosphor particulates have themselves been encapsulated before dispersion in an LED device encapsulant, in an effort to further reduce their moisture absorption. Other elements of LED device structure and fabrication may cause or enable further moisture absorption or intrusion into the LED device.

Moisture that is absorbed by encapsulants or phosphors or that otherwise intrudes into an LED device may lead to degradation or catastrophic failure of the device. As an example, incorporation of an LED device into an electrical circuit may be accomplished by soldering the anode and cathode leads to conductive pads communicating with the circuit. When the hot solder contacts the leads, heat transferred through the leads into the LED device may transform moisture within the LED device into superheated steam. This superheated steam may cause the LED device to either fracture or explode, the latter event being commonly referred to as “pop-corning”. As one measure taken to reduce moisture absorption by LED devices before soldering, the LED devices may be stored in moisture barrier envelopes that may include a dessicant. The user of LED devices so stored may be instructed to either keep the LED devices in the envelope until use, or to bake them dry prior to soldering. Punctures in plastic moisture barrier envelopes used for this protective storage may defeat the moisture barrier. In large scale manufacturing operations, equipment for automated placement and soldering of LED devices into circuits for applying a bias voltage may have to be housed in a moisture-controlled environment.

Soldering of LED devices may involve reflowing of the solder after initial solder application, in order to cause the LED devices to be accurately centered by capillary forces on pre-positioned conductive pads. The reflow step involves a reheating of the solder that may itself result in moisture-induced failure of LED devices. Sometimes, aqueous rinsing steps are also needed in fabrication of the circuits incorporating LED devices. In order to avoid resulting moisture absorption by or intrusion into the LED devices, these rinsing steps may need to be delayed until after the reflow is concluded. Alternatively, the user may need to bake the LED devices dry before the reflow step, which may not remove all of the moisture.

LED devices that have been successfully integrated into an electrical circuit may also suffer failure due to moisture absorption or intrusion during their end-use. LEDs generate substantial heat energy during light generation, causing the LED devices to undergo repeated heating and cooling cycles in use. If moisture becomes absorbed by or otherwise intrudes into an LED device during these heating and cooling cycles, subsequent heating cycles may cause fractures or pop-corning of the device.

LED devices are incorporated into circuits for diverse end use applications using a multitude of fabrication procedures. Special handling processes for such fabrication procedures that may be required in order to minimize moisture-induced LED device failure during circuit fabrication represent a constraint on and an extra cost of these fabrication procedures. Moisture may also lead to shortened LED device lifetimes. Consequently, there is a continuing need to provide new LED device structures having improved protection against moisture absorption and intrusion.

### SUMMARY

A new LED device incorporating a moisture-resistant seal and having a ceramic substrate (“Moisture-Resistant LED Device with Ceramic Substrate”) is described.

The Moisture-Resistant LED Device with Ceramic Substrate may include a ceramic substrate having a concave cavity, a light emitting diode (“LED”) in the concave cavity, a filler body over the LED, and a window sealed at an interface with the ceramic substrate. As an example, the Moisture-Resistant LED Device with Ceramic Substrate may include surface mount (“SMT”) electrode leads passing through the interface. In another example, the Moisture-Resistant LED Device with Ceramic Substrate may include a ceramic substrate having a lateral side, and SMT electrode leads may pass through a lateral side. As a further example, the Moisture-Resistant LED Device with Ceramic Substrate may include a ceramic substrate having a base, and through-hole mount (“through-hole”) electrode leads may pass through the substrate base. In another example, the ceramic substrate and window may be hermetically sealed together.

A method of making a Moisture-Resistant LED Device with Ceramic Substrate is also described. The method may include forming a ceramic substrate having a concave cavity, placing an LED in the concave cavity, forming a filler body over the LED, and forming and sealing a window at an interface with the ceramic substrate. As an example, the method may include hermetically sealing the ceramic substrate and window together.

Other systems, methods and features of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. In the figures, like reference numerals designate corresponding parts throughout the different views.

FIG. 1 shows a cross-sectional view of an example of a new Moisture-Resistant LED Device with Ceramic Substrate;

FIG. 2 shows a further cross-sectional view taken on line 2-2 of the Moisture-Resistant LED Device with Ceramic Substrate shown in FIG. 1;

FIG. 3 shows a flowchart illustrating an example of a method for fabricating the Moisture-Resistant LED Device with Ceramic Substrate shown in FIGS. 1 and 2;

FIG. 4 shows a cross-sectional view of an example of another Moisture-Resistant LED Device with Ceramic Substrate;

FIG. 5 shows a further cross-sectional view taken on line 5-5 of the Moisture-Resistant LED Device with Ceramic Substrate shown in FIG. 4;

FIG. 6 shows a flowchart illustrating an example of a method for fabricating the Moisture-Resistant LED Device with Ceramic Substrate shown in FIGS. 4 and 5;

FIG. 7 shows a cross-sectional view of an example of yet another Moisture-Resistant LED Device with Ceramic Substrate;

FIG. 8 shows a further cross-sectional view taken on line 8-8 of the Moisture-Resistant LED Device with Ceramic Substrate shown in FIG. 7;

FIG. 9 shows a flowchart illustrating an example of a method for fabricating the Moisture-Resistant LED Device with Ceramic Substrate shown in FIGS. 7 and 8.

FIG. 10 shows a cross-sectional view of an example of a further Moisture-Resistant LED Device with Ceramic Substrate; and

FIG. 11 shows a further cross-sectional view taken on line 11-11 of the Moisture-Resistant LED Device with Ceramic Substrate shown in FIG. 10;

### DETAILED DESCRIPTION

In the following description of various implementations, reference is made to the accompanying drawings that form a part of this disclosure, and which show, by way of illustration, specific implementations in which the invention may be practiced. Other implementations may be utilized and structural changes may be made without departing from the scope of the present invention.

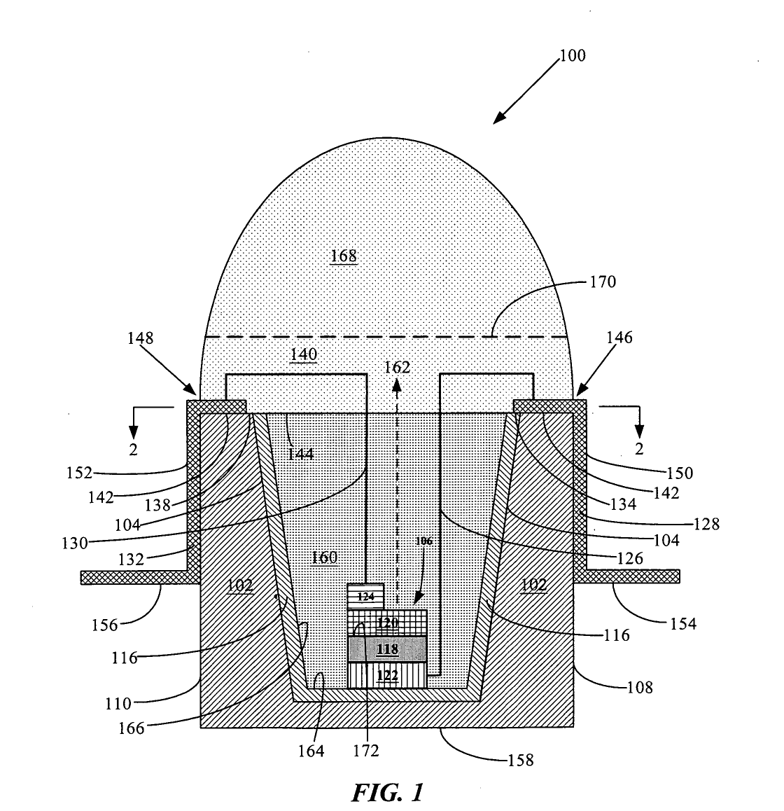

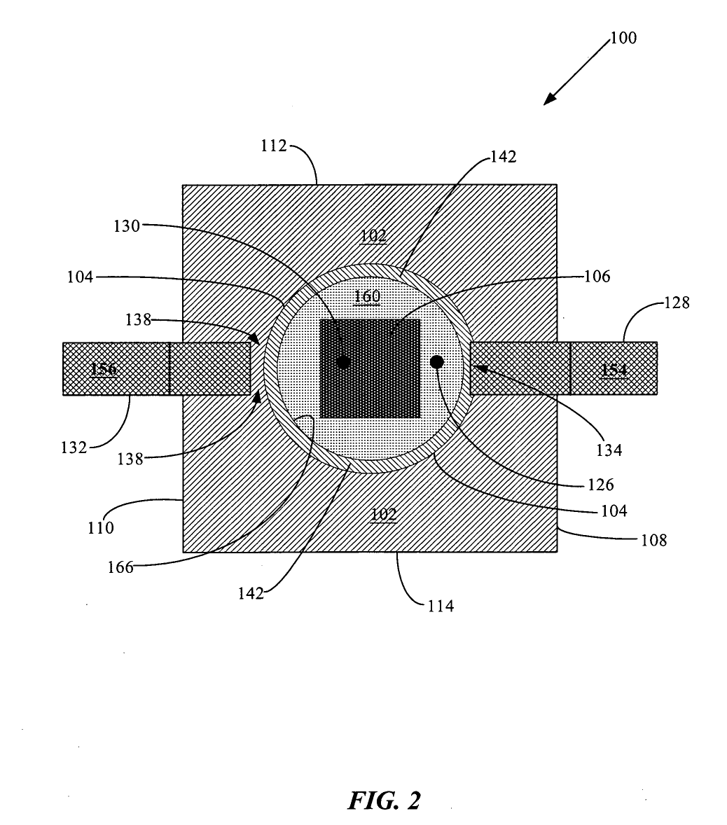

In FIG. 1, a cross-sectional view is shown of an example of an implementation of a Moisture-Resistant LED Device with Ceramic Substrate 100. In FIG. 2, a further cross-sectional view is shown, taken on line 2-2 in FIG. 1, of the Moisture-Resistant LED Device with Ceramic Substrate 100. The Moisture-Resistant LED Device with Ceramic Substrate 100 includes a ceramic substrate 102 having a concave (i.e., bowl shaped, cup-shaped, or bowl and cup shaped) cavity 104, in which an LED 106 is placed. As an example, the ceramic substrate 102 may have square lateral sides 108, 110, 112 and 114. In another example, the lateral sides, as best seen in FIG. 2, may collectively form another shape such as a pentagon, rectangle, circle or ellipse.

As an example, the ceramic substrate 102 may have a high electrical resistance. The ceramic substrate 102 may be fabricated from, as examples, alumina, aluminum nitride, aluminum silicate or sillimanite, barium neodymium titanate, barium strontium titanate (BST), barium tantalate, barium titanate (BT), beryllia, boron nitride, calcium titanate, calcium magnesium titanate (CMT), glass ceramic, cordierite/magnesium aluminum silicate, forsterite/magnesium silicate, lead magnesium niobate (PMN), lead zinc niobate (PZN), lithium niobate (LN), magnesium silicate, magnesium titanate, niobate or niobium oxide, porcelain, quartz, sapphire, strontium titanate, silica or silicate, steatite, tantalate or tantalum oxide, titania or titanate, zircon, zirconia or zirconate, and zirconium tin titanate. As another example, the ceramic substrate 102 may have a high resistance to moisture absorption.

The concave cavity 104 may include a light-reflective body 116 formed of, as an example, an optically-reflective metal or polymeric or metal and polymenc composition. It is appreciated by those skilled in the art that the term “body” broadly means and includes all forms of a mass of a subject device element, such as, for example, a layer, multiple layers, a coating, a casting, or a block, of any suitable dimensions, however formed.

The LED 106 may include a p-doped semiconductor body 118 and an n-doped semiconductor body 120. As an example, the shape of the LED 106 as seen in FIG. 2 may be a rectangular prism. In other examples, the shape of the LED 106 as seen in FIG. 2 may be cubic, cylindrical, or have another selected geometric shape. As an example, more than one LED 106 may be placed in the concave cavity 104.

The p-doped semiconductor body 118 may be in signal communication with a base conductor 122 and the n-doped semiconductor body 120 may be in signal communication with a top conductor 124. The base conductor 122 and top conductor 124 allow current to flow in and out of the p-doped semiconductor body 118 and n-doped semiconductor body 120, respectively. A cathode bonding wire 126 may electrically connect the base conductor 122 with a cathode electrode 128. Similarly, an anode bonding wire 130 may electrically connect the top conductor 124 with an anode electrode 132. As an example, more than one cathode bonding wire 126 or more than one anode bonding wire 130, or more than one of each of such wires, may be used.

In an example, the light-reflective body 116 may be formed of an electrical conductor, and the light-reflective body 116 may be placed in direct electrical communication with the cathode electrode 128 at point 134. An electrically-insulating gap 138 may then be provided between the light-reflective body 116 and the anode electrode 132, and the base conductor 122 and the cathode bonding wire 126 may be omitted.

It will be appreciated that in an alternative example structure for the Moisture-Resistant LED Device with Ceramic Substrate 100, the semiconductor body 120 may be p-doped and the semiconductor body 118 may be n-doped. A current flow through the LED 106 in such an alternative structure may be reversed, so that the Moisture-Resistant LED Device with Ceramic Substrate 100 may include an anode electrode 128 and a cathode electrode 132. As another example, the cathode electrode 128 may be replaced by a first terminal 128 at a relatively high electrical potential in signal communication with the p-doped semiconductor body 118; and the anode electrode 132 may be replaced by a second terminal 132 at a relatively low electrical potential in signal communication with the n-doped semiconductor body 120.

The Moisture-Resistant LED Device with Ceramic Substrate 100 may include a window 140 formed of a material having selected optical transmittance and a high resistance to moisture absorption, such as silicon dioxide. The window 140 may be formed in contact with a peripheral surface 142 of the ceramic substrate 102 best seen in FIG. 2, making a moisture-resistant seal between the ceramic substrate 102 and the window 140 at an interface 144. As an example, the cathode electrode 128 may enter the Moisture-Resistant LED Device with Ceramic Substrate 100, at a point 146, in contact with and sealed to the peripheral surface 142 of the ceramic substrate 102 and in contact with and sealed to the window 140. As an example, the anode electrode 132 may enter the Moisture-Resistant LED Device with Ceramic Substrate 100, at a point 148, in contact with and sealed to the peripheral surface 142 of the ceramic substrate 102 and in contact with and sealed to the window 140. In this manner, the ceramic substrate 102, the window 140, the cathode electrode 128 and the anode electrode 132 may be mutually sealed together, collectively forming a moisture-resistant package for the LED device 100. In an example, the ceramic substrate 102, the window 140, the cathode electrode 128 and the anode electrode 132 may together form a package for the LED device 100 that is hermetically sealed against moisture absorption or intrusion at the temperatures and pressures of typical utilization of LED devices for generating light.

As an example, the optical transmittance of the window 140 may be selected dependent upon the intended end-use for the Moisture-Resistant LED Device with Ceramic Substrate 100. In an example where the Moisture-Resistant LED Device with Ceramic Substrate 100 may be a phosphor-conversion device to be utilized to generate white light, the window 140 may be formed of a material selected for high transmission and low absorption of light wavelengths emitted by the LED 106 and of light wavelengths emitted by the phosphor, as further discussed below.

As an example, a portion 150 of the cathode electrode 128 and a portion 152 of the anode electrode 132 may be mounted in contact with the lateral sides 108 and 110, respectively, of the ceramic substrate 102. As a further example, a portion 154 of the cathode electrode 128 and a portion 156 of the anode electrode 132 may project away from the lateral sides 108 and 110, respectively, of the ceramic substrate 102. The portion 154 and the portion 156 may have various lengths that may be equal or unequal, and may be formed in various shapes and arranged in various positions so that the Moisture-Resistant LED Device with Ceramic Substrate 100 may be utilized in a surface-mount (“SMT”) end-use application. As an example, a base 158 of the ceramic substrate 102 may be placed in proximity to or in contact with an LED device mounting surface (not shown) such as a printed circuit board. The portion 154 of the cathode electrode 128 and the portion 156 of the anode electrode 132 may then be placed in electrical communication with conductive elements (not shown) on the printed circuit board. As an example, the conductive elements may be conductive pads.

A filler body 160 formed of a material having selected optical transmittance may cover the LED 106 and fill all or a portion of the concave cavity 104 up to the interface 144. As an example, the filler body 160 may be formed of a material selected for high transmission and low absorption of light wavelengths emitted by the LED 106 and of any phosphor that is dispersed in the filler body or otherwise located in the concave cavity 104.

As an example, the filler body 160 may be formed of a curable polymeric resin, such as an epoxy, silicone or acrylate resin (such as polymethyl-methacrylate for example), or a mixture of such resins. In an example, the filler body 160 may be formed of another photonic radiation-transmissive material, such as an inorganic glass that may be applied in the form of a sol-gel, for example.

The concave cavity 104 may form a reflector for photons emitted by the LED 106. The reflector may generally deflect these photons in the direction of an arrow 162 indicating an orientation of maximum photonic radiation from the Moisture-Resistant LED Device with Ceramic Substrate 100. In an example, the depth of the filler body 160 in the direction of the arrow 162 may traverse most of the height of the ceramic substrate 102 in the same direction. As another example, the depth of the filler body 160 in the direction of the arrow 162 may traverse a lesser portion of the height of the ceramic substrate 102 in the same direction, such as about half or less than about half of such height. As an example, a base inner wall 164 of the concave cavity 104 may have a circular circumference and a side inner wall 166 of the concave cavity 104 may also have a circular circumference that may be substantially uniform along or expand in the direction of the arrow 162. It is appreciated by those skilled in the art, however, that the base inner wall 164 and the side inner wall 166 may also have circumferences of other shapes and orientations. For example, the base inner wall 164 may have a circumference that is elliptical, quadrilateral, or of some other geometric shape. As an example, the circumference of the base inner wall 164 may have at least one axis of symmetry, and the shape of the circumference of the side inner wall 166 may be similar to that of the base inner wall 164.

As an example, a convex lens 168 may be provided over and in contact with the window 140 at an interface indicated by the dotted line 170. The convex lens 168 may serve to further focus the photonic emissions from the Moisture-Resistant LED Device with Ceramic Substrate 100. In an example, the convex lens 168 and the window 140 may be integrally formed of a material having selected optical transmittance and a high resistance to moisture absorption, such as silicon dioxide. In that case, the interface indicated by the dotted line 170 may be omitted. As another example, the convex lens 168 may be a diffused lens. The diffused lens may include dispersed light-scattering particles such as titanium dioxide or silicon dioxide particles, or particles of another metal oxide.

In an example of operation, a bias current may be applied across the cathode electrode 128 and the anode electrode 132 by an external power source, not shown. The bias current may induce charge carriers to be transported across an interface 172 between the n-doped semiconductor body 120 and the p-doped semiconductor body 118. Electrons may flow from the n-doped semiconductor body 120 to the p-doped semiconductor body 118, and holes may be generated in the opposite direction. Electrons injected into the p-doped semiconductor body 118 may recombine with the holes, resulting in electroluminescent emission of photons from the LED 106.

As a further example, the Moisture-Resistant LED Device with Ceramic Substrate 100 may be a phosphor-converting LED device having a selected phosphor composition dispersed in a region of or throughout the filler body 160. The selected phosphor composition may as an example be dispersed in a suitable encapsulant in a liquid phase and then deposited in the concave cavity 104.

In an example of operation, electroluminescent emissions from the LED 106 itself at one wavelength may be partially intercepted by the phosphor, resulting in stimulated luminescent emissions from the phosphor, that are usually at a longer wavelength than that of the electroluminescent emissions. Photons emitted by the LED 106 at a first wavelength and by the phosphor at a second wavelength may then be additively emitted from the Moisture-Resistant LED Device with Ceramic Substrate 100. It is appreciated by those skilled in the art that the LED as an example may be designed to emit blue photons, and the phosphor composition may be designed to emit yellow photons, in ratios where the additive output may be perceived by the human eye as white light.

As an example, if photonic emissions interpreted by the human eye as white light are selected, the LED 106 may be designed to emit blue light. Gallium nitride-(“GaN—”) or indium-gallium-nitride (“InGaN—”) based LED semiconductor chips emitting blue light with an emission maximum broadly within a range of about 420 nanometers (“nm”) to about 490 nm, or more particularly within a range of about 430 nm to about 480 nm, may be utilized. The term “GaN— or InGaN-based LED” is to be understood as being an LED whose radiation-emitting region contains GaN, InGaN, or either or both of these nitrides together with other related nitrides, as well as compositions further including mixed crystals based on any of these nitrides, such as Ga(Al—In)N, for example. Such LEDs are known, for example, from Shuji Nakamura and Gerhard Fasol, “The Blue Laser Diode”, Springer Verlag, Berlin/Heidelberg, 1997, pp. 209 et seq., the entirety of which hereby is incorporated herein by reference. In another example, a polymer LED or a laser diode may be utilized instead of the semiconductor LED. It is appreciated that the term “light emitting diode” is defined as encompassing and including, as examples, semiconductor light emitting diodes, polymer light emitting diodes, and laser diodes.

The choice of phosphor compositions for excitation by some of the blue photons emitted by the LED also may be determined by the selected end use application for the Moisture-Resistant LED Device with Ceramic Substrate 100. As an example, if photonic emissions interpreted by the human eye as white light are selected, the selected phosphor may be designed to emit yellow light. When combined in appropriate ratios at appropriate wavelengths as shown, for example, in chromaticity charts published by the International Commission for Illumination, the blue and yellow photons may appear together to the eye as white light. In this regard, yttrium aluminum garnet (“YAG”) is a common host material, and is usually doped with one or more rare-earth elements or compounds. Cerium is a common rare-earth dopant in YAG phosphors utilized for white light emission applications.

As an example, the selected phosphor composition may be a cerium-doped yttrium-aluminum garnet including at least one element such as yttrium, lutetium, selenium, lanthanum, gadolinium, samarium, or terbium. The cerium-doped yttrium-aluminum garnet may also include at least one element such as aluminum, gallium, or indium. As an example, the selected phosphor may have a cerium-doped garnet structure A₃B₅O₁₂, where the first component “A” represents at least one element such as yttrium (“Y”), lutetium (“Lu”), selenium (“Se”), lanthanum (“La”), gadolinium (“Gd”), samarium (“Sm”), or terbium (“Th”) and the second component “B” represents at least one element such as aluminum (Al), gallium (Ga), or indium (In). These phosphors may be excited by blue light from the LED 106 and in turn may emit light whose wavelength is shifted into the range above 500 nm, ranging up to about 585 nm. As an example, a phosphor may be utilized having a wavelength of maximum emission that is within a range of about 550 nm to about 585 nm. In the case of cerium-activated Th-garnet luminescent materials, the emission maximum may be at about 550 nm. Relatively small amounts of Th in the host lattice may serve the purpose of improving the properties of cerium-activated luminescent materials, while larger amounts of Th may be added specifically to shift the emission wavelength of cerium-activated luminescent materials. A high proportion of Th is therefore well suited for white phosphor-converted LED devices with a low color temperature of less than 5000 K. For further background information on phosphors for use in phosphor-converted LED devices, see for example: published Patent Cooperation Treaty documents WO 98/05088; WO 97/50132; WO 98/12757; and WO 97/50132, which are herein incorporated by reference in their entirety.

As an example, a blue-emitting LED based on gallium nitride or indium-gallium nitride, with emission maxima within a range of about 430 nm to about 480 nm, may be utilized to excite a luminescent material of the YAG:Ce type with emission maxima within a range of about 526 nm to about 585 nm.

Various examples have been described where a Moisture-Resistant LED Device with Ceramic Substrate may be designed to combine blue photons generated by electroluminescence emitted by LED 106 with yellow photons generated from blue photon-stimulated luminescence of a phosphor element, in order to provide light output having a white appearance. However, it is appreciated that Moisture-Resistant LED Devices with Ceramic Substrates operating with different chromatic schemes may also be designed for producing light that appears to be white or appears to have another color. Light that appears to be white may be realized through many combinations of two or more colors generated by LED 106 electroluminescence and photon-stimulated phosphor luminescence. One example method for generation of light having a white appearance is to combine light of two complementary colors in the proper power ratio.

With regard to the LED 106 itself, photon-emitting diode p-n junctions are typically based on two selected mixtures of Group III and Group V elements, such as gallium arsenide, gallium arsenide phosphide, or gallium phosphide. Careful control of the relative proportions of these compounds, and others incorporating aluminum and indium, as well as the addition of dopants such as tellurium and magnesium, enables production of LEDs that emit, for example, red, orange, yellow, or green light. As an example, the following semiconductor compositions (designated by epitaxial layers/LED substrate) may be utilized to generate photons in the corresponding output wavelength ranges and colors indicated in parentheses: gallium-aluminum-arsenide/gallium arsenide (880 nm, infrared); gallium-aluminum-arsenide/gallium-aluminum-arsenide (660 nm, ultra red); aluminum-gallium-indium-phosphide (633 nm, super red); aluminum-gallium-indium-phosphide (612 nm, super orange); gallium-arsenide/gallium-phosphide (605 nm, orange); gallium-arsenide-phosphide/gallium-phosphide (585 nm, yellow); indium-gallium-nitride/silicon-carbide (color temperature 4500K, incandescent white); indium-gallium-nitride/silicon-carbide (6500K, pale white); indium-gallium-nitride/silicon-carbide (8000K, cool white); gallium-phosphide/gallium-phosphide (555 nm, pure green); gallium-nitride/silicon-carbide (470 nm, super blue); gallium-nitride/silicon-carbide (430 nm, blue violet); and indium-gallium-nitride/silicon-carbide (395 nm, ultraviolet).

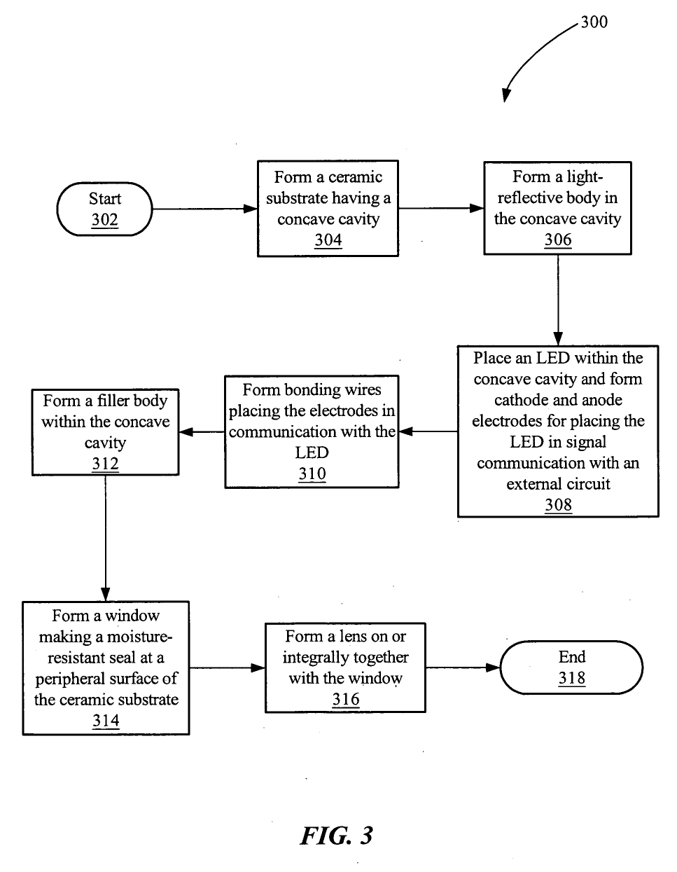

In FIG. 3, a flowchart 300 is shown illustrating an example of an implementation of a process for fabricating the Moisture-Resistant LED Device with Ceramic Substrate 100 shown in FIGS. 1 and 2. The process begins in step 302, and in step 304, a ceramic substrate 102 is provided, having a concave cavity 104. In step 306, a light-reflective body 116 may be provided in the concave cavity 104. As an example, the light-reflective body 116 may be formed as a coating on the base inner wall 164 and on the side inner wall 166 of the ceramic substrate 102.

In step 308, an LED 106 may be placed within the concave cavity 104 on the base inner wall 164. Also in step 308, a cathode electrode 128 and an anode electrode 132 may be provided for placing the LED 106 in signal communication with an external circuit (not shown). The cathode electrode 128 and the anode electrode 132 may be positioned so that a portion of each electrode is on a peripheral surface 142 of the ceramic substrate 102 so that the electrodes may provide signal communication between the LED 106 and the external circuit at the peripheral surface 142. In an example, the cathode electrode 128 may enter the Moisture-Resistant LED Device with Ceramic Substrate 100 at a point 146, and the anode electrode 132 may enter the device 100 at a point 148. As an example, the light-reflective body 116 may be formed of an electrically-conductive material, and the portion of the cathode electrode 128 may be placed in direct signal communication with the light-reflective body 116 at point 134. As an example, the portion of the anode electrode 132 may be spaced apart from the light-reflective body 116 by an insulating gap 138, preventing direct signal communication between the anode electrode 132 and the light-reflective body 116. Portions 150 and 152 of the cathode electrode 128 and the anode electrode 132, respectively, may be formed adjacent to the lateral sides 108 and 110 respectively of the ceramic substrate 102. Portions 154 and 156 of the cathode electrode 128 and the anode electrode 132, respectively, may be positioned to project away from the lateral sides 108 and 110 respectively of the ceramic substrate 102.

The LED 106 may be pre-made, or formed in situ. The LED 106 may be an example, positioned at a point on the base inner wall 164 substantially equidistant from all points at which base inner wall 164 meets side inner wall 166. The LED 106 may be fabricated using various known techniques such as, for example, liquid phase epitaxy, vapor phase epitaxy, metal-organic epitaxial chemical vapor deposition, or molecular beam epitaxy.

In step 310, a cathode bonding wire 126 may be provided, placing the cathode electrode 128 in direct signal communication with a base conductor 122 of the LED 106. In a case where the cathode electrode 128 is placed in signal communication with an electrically conductive light-reflective body 116, the base conductor 122 and the cathode bonding wire 126 may be omitted. Also in step 310, an anode bonding wire 130 may be provided, placing the anode electrode 132 in direct signal communication with a top conductor 124 of the LED 106.

In step 312, a filler body 160 may be provided in the concave cavity 104. As an example, the filler body 160 may completely fill the concave cavity 104 over the LED 106 to the interface 144. The filler body 160 may be formed from, as an example, an encapsulant composition as earlier discussed. In an example, the encapsulant composition may include a phosphor as earlier discussed. As another example, an encapsulant composition including a phosphor may fill a selected region of the concave cavity 104, and an encapsulant without a phosphor may fill another selected region of the concave cavity. The encapsulant may be formed, as an example, by depositing a liquid encapsulant composition in the concave cavity 104. In an example, the liquid encapsulant composition may then be converted to a solid state.

In step 314, a window 140 may be provided that forms a moisture-resistant seal at the peripheral surface 142 of the ceramic substrate 102. The window 140 may have a substantially flat surface as indicated by the dotted line 170. As an example, the window 140 may be formed of a material having a high resistance to moisture absorption. In an example, the window 140 may be formed of an optically transparent material such as an optically transparent inorganic oxide. Silicon dioxide, as an example, may form a moisture resistant seal with the ceramic substrate 102. In one example, the window 140 may be formed in-situ from an inorganic sol-gel composition. As another example, the window 140 may form a hermetic seal against moisture with the ceramic substrate 102, the cathode electrode 128 and the anode electrode 132, so that absorption or intrusion of moisture into the Moisture-Resistant LED Device with Ceramic Substrate 100 may be substantially avoided, or reduced to a level that substantially reduces pop-coming of the LED devices during soldering and end-use.

In an example, the process 300 may include step 316, in which a lens 168 may be provided on or integrally formed with the window 140. The lens may be, as an example, a diffused lens. In an example, the lens 168 may be formed of a material having a high resistance to moisture absorption and having selected optical transmittance. The lens may, as an example, include dispersed light-scattering particles. The lens 168 may, in an example, be formed with a selected dome shape by molding or casting. In another example, the window 140 and the lens 168 may be integrally formed. The process then ends in step 318. It is appreciated that the order of steps in the process 300 may be changed.

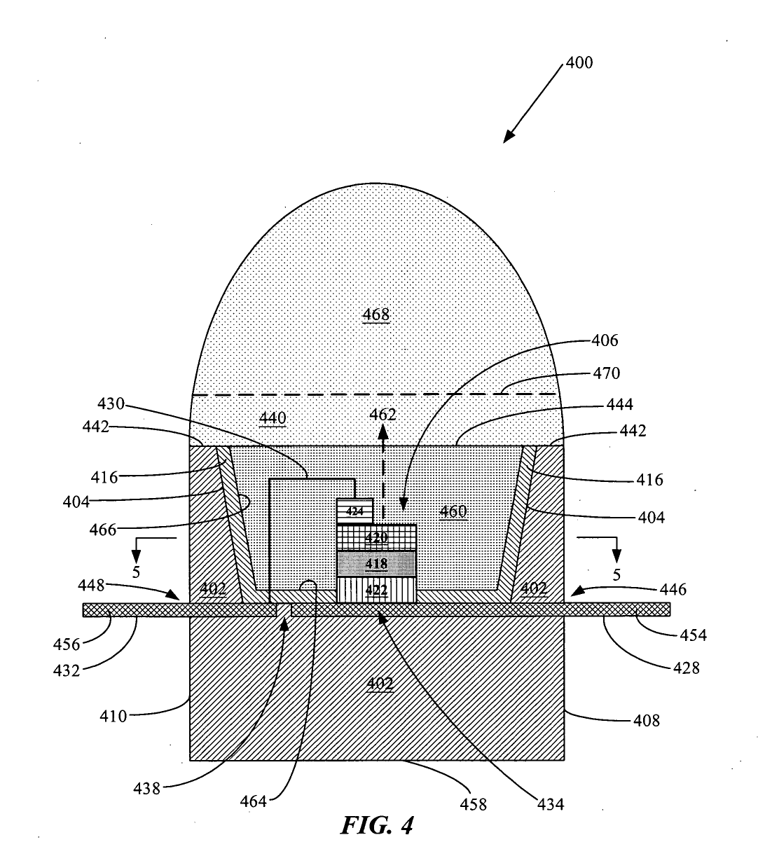

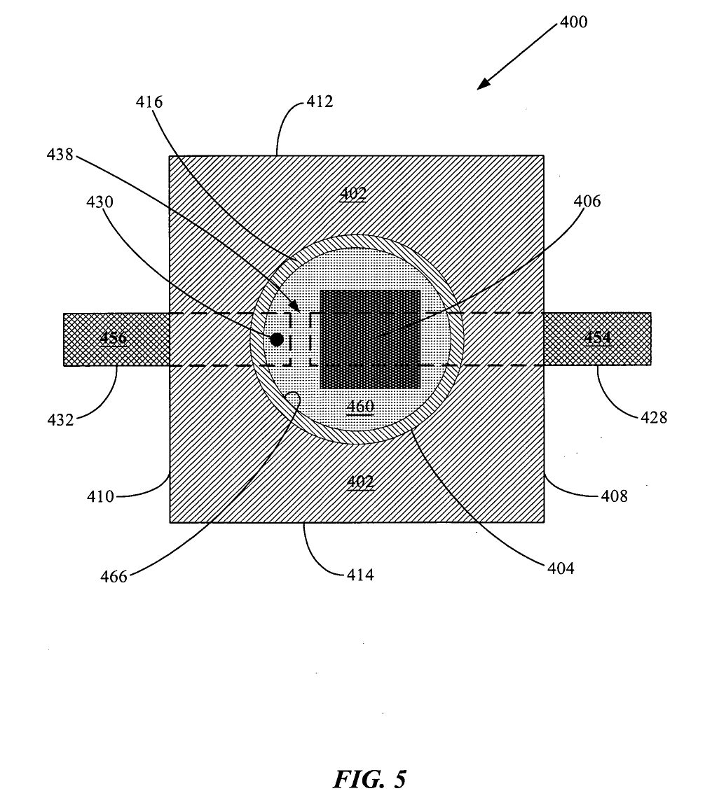

In FIG. 4, a cross-sectional view is shown of another example of an implementation of a Moisture-Resistant LED Device with Ceramic Substrate 400. In FIG. 5, a further cross-sectional view is shown, taken on line 5-5 in FIG. 4, of the Moisture-Resistant LED Device with Ceramic Substrate 400. The Moisture-Resistant LED Device with Ceramic Substrate 400 includes a ceramic substrate 402 having a concave cavity 404, in which an LED 406 is placed. As an example, the ceramic substrate 402 may have square lateral sides 408, 410, 412 and 414. In another example, the lateral sides, as best seen in FIG. 5, may collectively form another shape such as a pentagon, rectangle, circle or ellipse. As an example, the ceramic substrate 402 may have a high electrical resistance. As another example, the ceramic substrate 402 may have a high resistance to moisture absorption. The concave cavity 404 may include a light-reflective body 416 formed of, as an example, an optically-reflective and non-conductive material. As an example, the light-reflective body 416 may be formed of a polymeric composition having a selected optical reflectance.

The LED 406 may include a p-doped semiconductor body 418 and an n-doped semiconductor body 420. As an example, the shape of the LED 406 as seen in FIG. 5 may be a rectangular prism. In other examples, the shape of the LED 406 as seen in FIG. 5 may be cubic, cylindrical, or have another selected geometric shape. As an example, more than one LED 406 may be placed in the concave cavity 404. The p-doped semiconductor body 418 may be in signal communication with a base conductor 422 and the n-doped semiconductor body 420 may be in signal communication with a top conductor 424. The base conductor 422 and top conductor 424 allow current to flow in and out of the p-doped semiconductor body 418 and n-doped semiconductor body 420, respectively.

The base conductor 422 may be placed in direct electrical communication with a cathode electrode 428 at point 434. As a further example, the base conductor 422 may be omitted and the p-doped semiconductor body 418 may be placed in direct contact with the cathode electrode 428. An anode bonding wire 430 may electrically connect the top conductor 424 with an anode electrode 432. As an example, more than one anode bonding wire 430 may be used. The cathode electrode 428 and the anode electrode 432 may be mutually spaced apart by an insulating gap 438.

It will be appreciated that in an alternative example structure for the Moisture-Resistant LED Device with Ceramic Substrate 400, the semiconductor body 420 may be p-doped and the semiconductor body 418 may be n-doped. A current flow through the LED 406 in such an alternative structure may be reversed, so that the Moisture-Resistant LED Device with Ceramic Substrate 400 may include an anode electrode 428 and a cathode electrode 432. As another example, the cathode electrode 428 may be replaced by a first terminal 428 at a relatively high electrical potential in signal communication with the p-doped semiconductor body 418; and the anode electrode 432 may be replaced by a second terminal 432 at a relatively low electrical potential in signal communication with the n-doped semiconductor body 420.

The Moisture-Resistant LED Device with Ceramic Substrate 400 may include a window 440 formed of a material having selected optical transmittance and a high resistance to moisture absorption. The window 440 may be formed in contact with a peripheral surface 442 of the ceramic substrate 402 best seen in FIG. 4, making a moisture-resistant seal between the ceramic substrate 402 and the window 440 at an interface 444. As an example, the cathode electrode 428 may enter the Moisture-Resistant LED Device with Ceramic Substrate 400, at a point 446 on the lateral side 408, in contact with and sealed to the ceramic substrate 402. As an example, the anode electrode 432 may enter the Moisture-Resistant LED Device with Ceramic Substrate 400, at a point 448 on the lateral side 410, in contact with and sealed to the ceramic substrate 402. In this manner, the ceramic substrate 402, the window 440, the cathode electrode 428 and the anode electrode 432 may be mutually sealed together, collectively forming a moisture-resistant package for the LED device 400. In an example, the ceramic substrate 402, the window 440, the cathode electrode 428 and the anode electrode 432 may together form a package for the LED device 400 that is hermetically sealed against moisture absorption or intrusion at the temperatures and pressures of typical utilization of LED devices for generating light.

As an example, the optical transmittance of the window 440 may be selected dependent upon the intended end-use for the Moisture-Resistant LED Device with Ceramic Substrate 400. In an example where the Moisture-Resistant LED Device with Ceramic Substrate 400 may be a phosphor-conversion device to be utilized to generate white light, the window 440 may be formed of a material selected for high transmission and low absorption of light wavelengths emitted by the LED 406 and of light wavelengths emitted by the phosphor.

As an example, a portion 454 of the cathode electrode 428 and a portion 456 of the anode electrode 432 may project away from the lateral sides 408 and 410, respectively, of the ceramic substrate 402. The portion 454 and the portion 456 may have various lengths that may be equal or unequal, and may be formed in various shapes and arranged in various positions so that the Moisture-Resistant LED Device with Ceramic Substrate 400 may be utilized in a surface-mount (“SMT”) end-use application. As an example, a base 458 of the ceramic substrate 402 may be placed in proximity to or in contact with an LED device mounting surface (not shown) such as a printed circuit board. The portion 454 of the cathode electrode 428 and the portion 456 of the anode electrode 432 may then be placed in electrical communication with conductive elements (not shown) on the printed circuit board. As an example, the conductive elements may be conductive pads.

A filler body 460 formed of a material having selected optical transmittance may cover the LED 406 and fill all or a portion of the concave cavity 404 up to the interface 444. As an example, the filler body 460 may be formed of a material selected for high transmission and low absorption of light wavelengths emitted by the LED 406 and of any phosphor that is dispersed in the filler body or otherwise located in the concave cavity 404.

As an example, the filler body 460 may be formed of a curable polymeric resin, or a mixture of such resins. In a further example, the filler body 460 may be formed of another photonic radiation-transmissive material, such as an inorganic glass that may be applied in the form of a sol-gel, for example.

The concave cavity 404 may form a reflector for photons emitted by the LED 406. The reflector may generally deflect these photons in the direction of an arrow 462 indicating an orientation of maximum photonic radiation from the Moisture-Resistant LED Device with Ceramic Substrate 400. In an example, the depth of the filler body 460 in the direction of the arrow 462 may traverse a selected portion of the height of the ceramic substrate 402 in the same direction. As an example, a base inner wall 464 of the concave cavity 404 may have a circular circumference and a side inner wall 466 of the concave cavity 404 may also have a circular circumference that may be substantially uniform along or expand in the direction of the arrow 462. It is appreciated by those skilled in the art, however, that the base inner wall 464 and the side inner wall 466 may also have circumferences of other shapes and orientations. For example, the base inner wall 464 may have a circumference that is elliptical, quadrilateral, or of some other geometric shape. As an example, the circumference of the base inner wall 464 may have at least one axis of symmetry, and the shape of the circumference of the side inner wall 466 may be similar to that of the base inner wall 464.

As an example, a convex lens 468 may be provided over and in contact with the window 440 at an interface indicated by the dotted line 470. The convex lens 468 may serve to further focus the photonic emissions from the Moisture-Resistant LED Device with Ceramic Substrate 400. In an example, the convex lens 468 and the window 440 may be integrally formed of a material having selected optical transmittance and a high resistance to moisture absorption. In that case, the interface indicated by the dotted line 470 may be omitted. As another example, the convex lens 468 may be a diffused lens. The diffused lens may include dispersed light-scattering particles.

As a further example, the Moisture-Resistant LED Device with Ceramic Substrate 400 may be a phosphor-converting LED device having a selected phosphor composition dispersed in a region of or throughout the filler body 460. The selected phosphor composition may as an example be dispersed in a suitable encapsulant in a liquid phase and then deposited in the concave cavity 404.

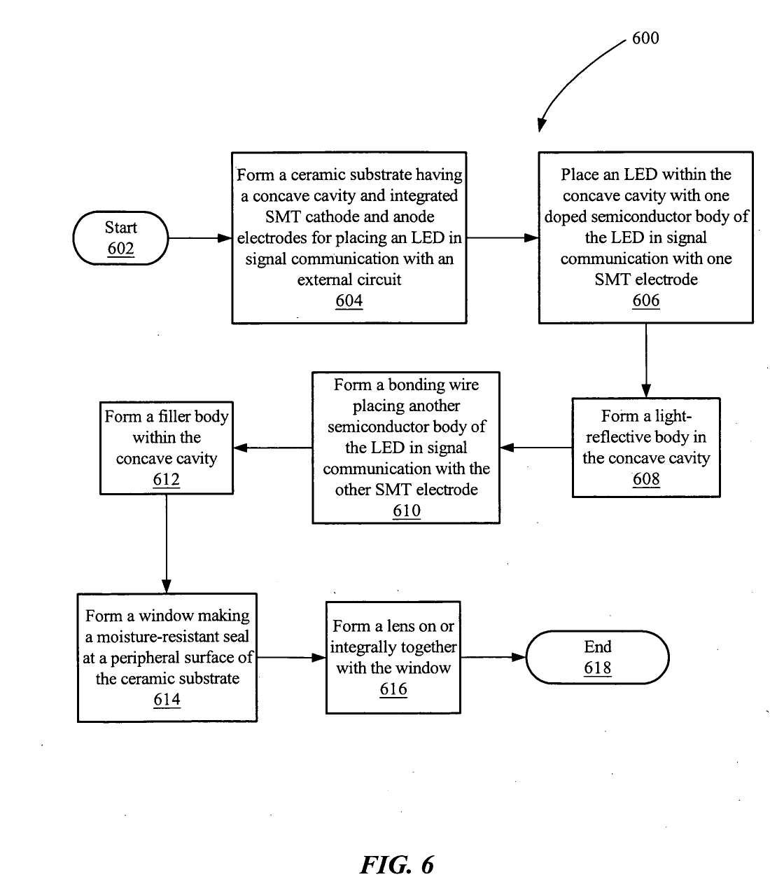

In FIG. 6, a flowchart 600 is shown illustrating an example of an implementation of a process for fabricating the Moisture-Resistant LED Device with Ceramic Substrate 400 shown in FIGS. 4 and 5. The process begins in step 602, and in step 604, a ceramic substrate 402 may be provided, having a concave cavity 404 with an integrated surface-mount (“SMT”) cathode electrode 428 and an integrated SMT anode electrode 432 for placing an LED 406 in signal communication with an external circuit (not shown). The cathode electrode 428 and the anode electrode 432 may be positioned so that a portion of each electrode is located immediately below the base inner wall 464 of the concave cavity 404. In an example, the cathode electrode 428 may enter the Moisture-Resistant LED Device with Ceramic Substrate 400 at a point 446 along the lateral side 408 of the ceramic substrate 402, and the anode electrode 432 may enter the device 400 at a point 448 along the lateral side 410 of the ceramic substrate. The cathode electrode 428 and the anode electrode 432 may be mutually spaced apart by an insulating gap 438. Portions 454 and 456 of the cathode electrode 428 and the anode electrode 432, respectively, may be positioned to project away from the lateral sides 408 and 410 respectively of the ceramic substrate 402.

In step 606, an LED 406 may be placed within the concave cavity 404 on the base inner wall 464. As an example, a base conductor 422 of the LED 406 may be placed in direct signal communication with the cathode electrode 428 at point 434. As another example, the base conductor 422 may be omitted and the p-doped semiconductor body 418 may be placed in direct signal communication with the cathode electrode 428 at point 434. The LED 406 may be pre-made, or formed in situ. The LED 406 may, as an example, be positioned at a point on the base inner wall 464 substantially equidistant from all points at which base inner wall 464 meets side inner wall 466.

In step 608, a light-reflective body 416 may be provided in the concave cavity 404. As an example, the light-reflective body 416 may be formed as a coating on the base inner wall 464 and on the side inner wall 466 of the ceramic substrate 402. In another example, the light-reflective body 416 may be formed of an optically-reflective and non-conductive material.

In step 610, an anode bonding wire 430 may be provided, placing the anode electrode 432 in direct signal communication with a top conductor 424 of the LED 406.

In step 612, a filler body 460 may be provided in the concave cavity 404. As an example, the filler body 460 may completely fill the concave cavity 404 over the LED 406 to the interface 444. The filler body 460 may be formed from, as an example, an encapsulant composition as earlier discussed. In an example, the encapsulant composition may include a phosphor as earlier discussed. As another example, an encapsulant composition including a phosphor may fill a selected region of the concave cavity 404, and an encapsulant without a phosphor may fill another selected region of the concave cavity. The encapsulant may be formed, as an example, by depositing a liquid encapsulant composition in the concave cavity 404. In an example, the liquid encapsulant composition may then be converted to a solid state.

In step 614, a window 440 may be provided that forms a moisture-resistant seal at the peripheral surface 442 of the ceramic substrate 402. The window 440 may have a substantially flat surface as indicated by the dotted line 470. As an example, the window 440 may be formed of a material having a high resistance to moisture absorption. In an example, the window 440 may be formed of an optically transparent material such as an optically transparent inorganic oxide. Silicon dioxide, as an example, may form a moisture resistant seal with the ceramic substrate 402. In one example, the window 440 may be formed in-situ from an inorganic sol-gel composition. As another example, the window 440 may form a hermetic seal against moisture with the ceramic substrate 402, so that absorption or intrusion of moisture into the Moisture-Resistant LED Device with Ceramic Substrate 400 may be substantially avoided, or reduced to a level that substantially reduces pop-corning of the LED devices during soldering and end-use.

In an example, the process 600 may include step 616, in which a lens 468 may be provided on or integrally formed with the window 440. The lens may be, as an example, a diffused lens. In an example, the lens 468 may be formed of a material having a high resistance to moisture absorption and having selected optical transmittance. The lens may, as an example, include dispersed light-scattering particles. The lens 468 may, in an example, be formed with a selected dome shape by molding or casting. In another example, the window 440 and the lens 468 may be integrally formed. The process then ends in step 618. It is appreciated that the order of steps in the process 600 may be changed.

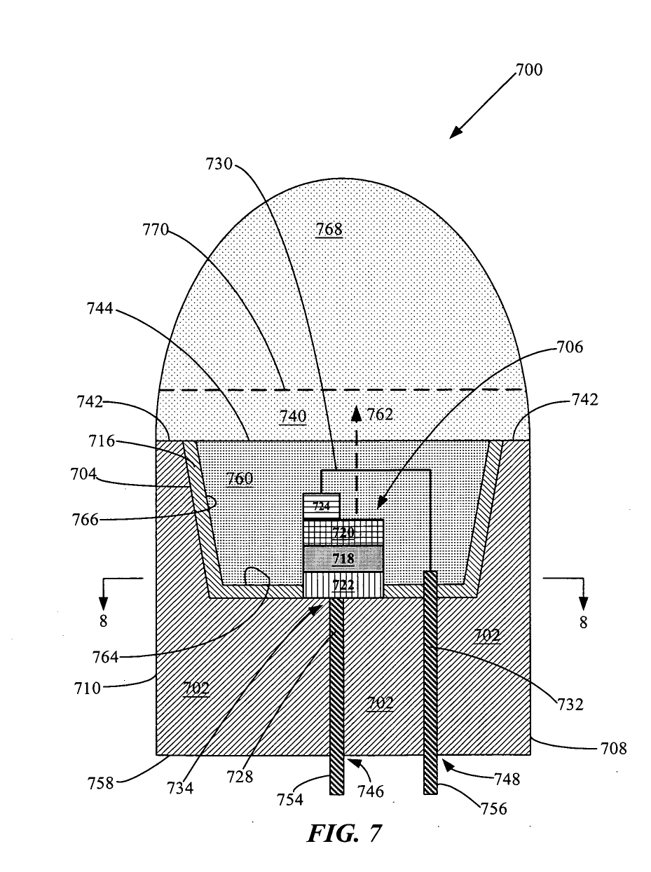

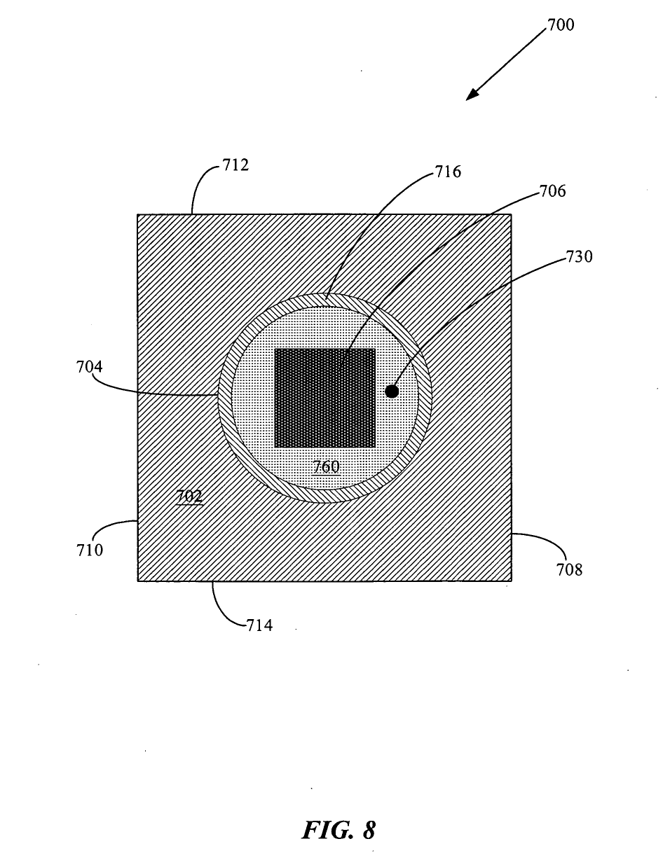

In FIG. 7, a cross-sectional view is shown of yet another example of an implementation of a Moisture-Resistant LED Device with Ceramic Substrate 700. In FIG. 8, a further cross-sectional view is shown, taken on line 8-8 in FIG. 7, of the Moisture-Resistant LED Device with Ceramic Substrate 700. The Moisture-Resistant LED Device with Ceramic Substrate 700 includes a ceramic substrate 702 having a concave cavity 704, in which an LED 706 is placed. As an example, the ceramic substrate 702 may have square lateral sides 708, 710, 712 and 714. In another example, the lateral sides, as best seen in FIG. 8, may collectively form another shape such as a pentagon, rectangle, circle or ellipse. As an example, the ceramic substrate 702 may have a high electrical resistance. As another example, the ceramic substrate 702 may have a high resistance to moisture absorption. The concave cavity 704 may include a light-reflective body 716 formed of, as an example, an optically-reflective and non-conductive material. As an example, the light-reflective body 716 may be formed of a polymeric composition having a selected optical reflectance.

The LED 706 may include a p-doped semiconductor body 718 and an n-doped semiconductor body 720. As an example, the shape of the LED 706 as seen in FIG. 8 may be a rectangular prism. In other examples, the shape of the LED 706 as seen in FIG. 8 may be cubic, cylindrical, or have another selected geometric shape. As an example, more than one LED 706 may be placed in the concave cavity 704. The p-doped semiconductor body 718 may be in signal communication with a base conductor 722 and the n-doped semiconductor body 720 may be in signal communication with a top conductor 724. The base conductor 722 and top conductor 724 allow current to flow in and out of the p-doped semiconductor body 718 and n-doped semiconductor body 720, respectively.

The base conductor 722 may be placed in direct electrical communication with a through-hole cathode electrode 728 at point 734. As a further example, the base conductor 722 may be omitted and the p-doped semiconductor body 718 may be placed in direct contact with the through-hole cathode electrode 728. An anode bonding wire 730 may electrically connect the top conductor 724 with a through-hole anode electrode 732. As an example, more than one anode bonding wire 730 may be used.

It will be appreciated that in an alternative example structure for the Moisture-Resistant LED Device with Ceramic Substrate 700, the semiconductor body 720 may be p-doped and the semiconductor body 718 may be n-doped. A current flow through the LED 706 in such an alternative structure may be reversed, so that the Moisture-Resistant LED Device with Ceramic Substrate 700 may include an anode electrode 728 and a cathode electrode 732. As another example, the cathode electrode 728 may be replaced by a first terminal 728 at a relatively high electrical potential in signal communication with the p-doped semiconductor body 718; and the anode electrode 732 may be replaced by a second terminal 732 at a relatively low electrical potential in signal communication with the n-doped semiconductor body 720.

The Moisture-Resistant LED Device with Ceramic Substrate 700 may include a window 740 formed of a material having selected optical transmittance and a high resistance to moisture absorption. The window 740 may be formed in contact with a peripheral surface 742 of the ceramic substrate 702 best seen in FIG. 7, making a moisture-resistant seal between the ceramic substrate 702 and the window 740 at an interface 744. As an example, the cathode electrode 728 may enter the Moisture-Resistant LED Device with Ceramic Substrate 700, at a point 746 on the base 758, in contact with and sealed to the ceramic substrate 702. As an example, the anode electrode 732 may enter the Moisture-Resistant LED Device with Ceramic Substrate 700, at a point 748 on the base 758, in contact with and sealed to the ceramic substrate 702. In this manner, the ceramic substrate 702, the window 740, the cathode electrode 728 and the anode electrode 732 may be mutually sealed together, collectively forming a moisture-resistant package for the LED device 700. In an example, the ceramic substrate 702, the window 740, the cathode electrode 728 and the anode electrode 732 may together form a package for the LED device 700 that is hermetically sealed against moisture absorption or intrusion at the temperatures and pressures of typical utilization of LED devices for generating light.

As an example, the optical transmittance of the window 740 may be selected dependent upon the intended end-use for the Moisture-Resistant LED Device with Ceramic Substrate 700. In an example where the Moisture-Resistant LED Device with Ceramic Substrate 700 may be a phosphor-conversion device to be utilized to generate white light, the window 740 may be formed of a material selected for high transmission and low absorption of light wavelengths emitted by the LED 706 and of light wavelengths emitted by the phosphor.

As an example, a portion 754 of the cathode electrode 728 and a portion 756 of the anode electrode 732 may project away from the base 758 of the ceramic substrate 702. The portion 754 and the portion 756 may have various lengths that may be equal or unequal, and may be formed in various shapes and arranged in various positions so that the Moisture-Resistant LED Device with Ceramic Substrate 700 may be utilized in a through-hole-mount (“through-hole”) end-use application. As an example, a base 758 of the ceramic substrate 702 may be placed in proximity to or in contact with an LED device mounting surface (not shown) such as a printed circuit board. The portion 754 of the cathode electrode 728 and the portion 756 of the anode electrode 732 may then be placed in electrical communication with conductive elements (not shown) on the printed circuit board. As an example, the conductive elements may be conductive pads.

A filler body 760 formed of a material having selected optical transmittance may cover the LED 706 and fill all or a portion of the concave cavity 704 up to the interface 744. As an example, the filler body 760 may be formed of a material selected for high transmission and low absorption of light wavelengths emitted by the LED 706 and of any phosphor that is dispersed in the filler body or otherwise located in the concave cavity 704.

As an example, the filler body 760 may be formed of a curable polymeric resin, or a mixture of such resins. In a further example, the filler body 760 may be formed of another photonic radiation-transmissive material, such as an inorganic glass that may be applied in the form of a sol-gel, for example. As a further example, the filler body 760 may be formed of a non-conductive material.

The concave cavity 704 may form a reflector for photons emitted by the LED 706. The reflector may generally deflect these photons in the direction of an arrow 762 indicating an orientation of maximum photonic radiation from the Moisture-Resistant LED Device with Ceramic Substrate 700. In an example, the depth of the filler body 760 in the direction of the arrow 762 may traverse a selected portion of the height of the ceramic substrate 702 in the same direction. As an example, a base inner wall 764 of the concave cavity 704 may have a circular circumference and a side inner wall 766 of the concave cavity 704 may also have a circular circumference that may be substantially uniform along or expand in the direction of the arrow 762. It is appreciated by those skilled in the art, however, that the base inner wall 764 and the side inner wall 766 may also have circumferences of other shapes and orientations. For example, the base inner wall 764 may have a circumference that is elliptical, quadrilateral, or of some other geometric shape. As an example, the circumference of the base inner wall 764 may have at least one axis of symmetry, and the shape of the circumference of the side inner wall 766 may be similar to that of the base inner wall 764.

As an example, a convex lens 768 may be provided over and in contact with the window 740 at an interface indicated by the dotted line 770. The convex lens 768 may serve to further focus the photonic emissions from the Moisture-Resistant LED Device with Ceramic Substrate 700. In an example, the convex lens 768 and the window 740 may be integrally formed of a material having selected optical transmittance and a high resistance to moisture absorption. In that case, the interface indicated by the dotted line 770 may be omitted. As another example, the convex lens 768 may be a diffused lens. The diffused lens may include dispersed light-scattering particles.

As a further example, the Moisture-Resistant LED Device with Ceramic Substrate 700 may be a phosphor-converting LED device having a selected phosphor composition dispersed in a region of or throughout the filler body 760. The selected phosphor composition may as an example be dispersed in a suitable encapsulant in a liquid phase and then deposited in the concave cavity 704.

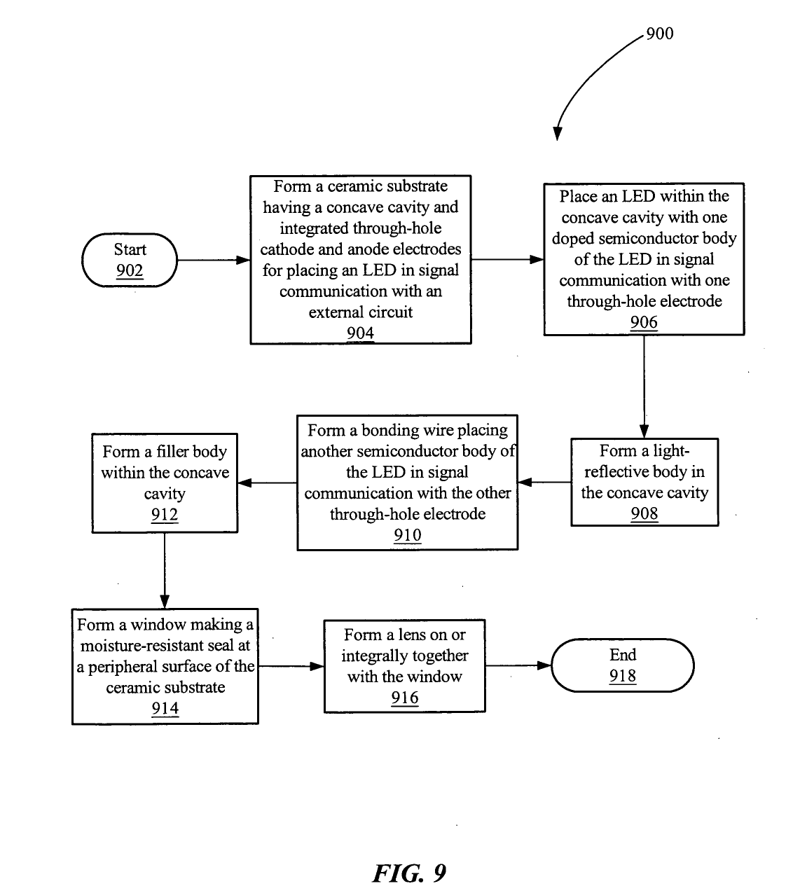

In FIG. 9, a flowchart 900 is shown illustrating an example of an implementation of a process for fabricating the Moisture-Resistant LED Device with Ceramic Substrate 700 shown in FIGS. 7 and 8. The process begins in step 902, and in step 904, a ceramic substrate 702 may be provided, having a concave cavity 704 with an integrated through-hole cathode electrode 728 and an integrated through-hole anode electrode 732 for placing an LED 706 in signal communication with an external circuit (not shown). The cathode electrode 728 and the anode electrode 732 may be positioned so that a terminal portion of each electrode is located immediately below the base inner wall 764 of the concave cavity 704. In an example, the cathode electrode 728 may enter the Moisture-Resistant LED Device with Ceramic Substrate 700 at a point 746 below the base inner wall 764 of the ceramic substrate 702, and the anode electrode 732 may enter the device 700 at a point 748 below the base inner wall 764 of the ceramic substrate. Portions 754 and 756 of the cathode electrode 728 and the anode electrode 732, respectively, may be positioned to project away from the base 758 of the ceramic substrate 702.

In step 906, an LED 706 may be placed within the concave cavity 704 on the base inner wall 764. As an example, a base conductor 722 of the LED 706 may be placed in direct signal communication with the cathode electrode 728 at point 734. As another example, the base conductor 722 may be omitted and the p-doped semiconductor body 718 may be placed in direct signal communication with the cathode electrode 728 at point 734. The LED 706 may be pre-made, or formed in situ. The LED 706 may, as an example, be positioned at a point on the base inner wall 764 substantially equidistant from all points at which base inner wall 764 meets side inner wall 766.

In step 908, a light-reflective body 716 may be provided in the concave cavity 704. As an example, the light-reflective body 716 may be formed as a coating on the base inner wall 764 and on the side inner wall 766 of the ceramic substrate 702. In another example, the light-reflective body 716 may be formed of an optically-reflective and non-conductive material.

In step 910, an anode bonding wire 730 may be provided, placing the anode electrode 732 in direct signal communication with a top conductor 724 of the LED 706.

In step 912, a filler body 760 may be provided in the concave cavity 704. As an example, the filler body 760 may completely fill the concave cavity 704 over the LED 706 to the interface 744. The filler body 760 may be formed from, as an example, an encapsulant composition as earlier discussed. In an example, the encapsulant composition may include a phosphor as earlier discussed. As another example, an encapsulant composition including a phosphor may fill a selected region of the concave cavity 704, and an encapsulant without a phosphor may fill another selected region of the concave cavity. The encapsulant may be formed, as an example, by depositing a liquid encapsulant composition in the concave cavity 704. In an example, the liquid encapsulant composition may then be converted to a solid state.

In step 914, a window 740 may be provided that forms a moisture-resistant seal at the peripheral surface 742 of the ceramic substrate 702. The window 740 may have a substantially flat surface as indicated by the dotted line 770. As an example, the window 740 may be formed of a material having a high resistance to moisture absorption. In an example, the window 740 may be formed of an optically transparent material such as an optically transparent inorganic oxide. Silicon dioxide, as an example, may form a moisture resistant seal with the ceramic substrate 702. In one example, the window 740 may be formed in-situ from an inorganic sol-gel composition. As another example, the window 740 may form a hermetic seal against moisture with the ceramic substrate 702, so that absorption or intrusion of moisture into the Moisture-Resistant LED Device with Ceramic Substrate 700 may be substantially avoided, or reduced to a level that substantially reduces pop-coming of the LED devices during soldering and end-use.

In an example, the process 900 may include step 916, in which a lens 768 may be provided on or integrally formed with the window 740. The lens may be, as an example, a diffused lens. In an example, the lens 768 may be formed of a material having a high resistance to moisture absorption and having selected optical transmittance. The lens may, as an example, include dispersed light-scattering particles. The lens 768 may, in an example, be formed with a selected dome shape by molding or casting. In another example, the window 740 and the lens 768 may be integrally formed. The process then ends in step 918. It is appreciated that the order of steps in the process 900 may be changed.

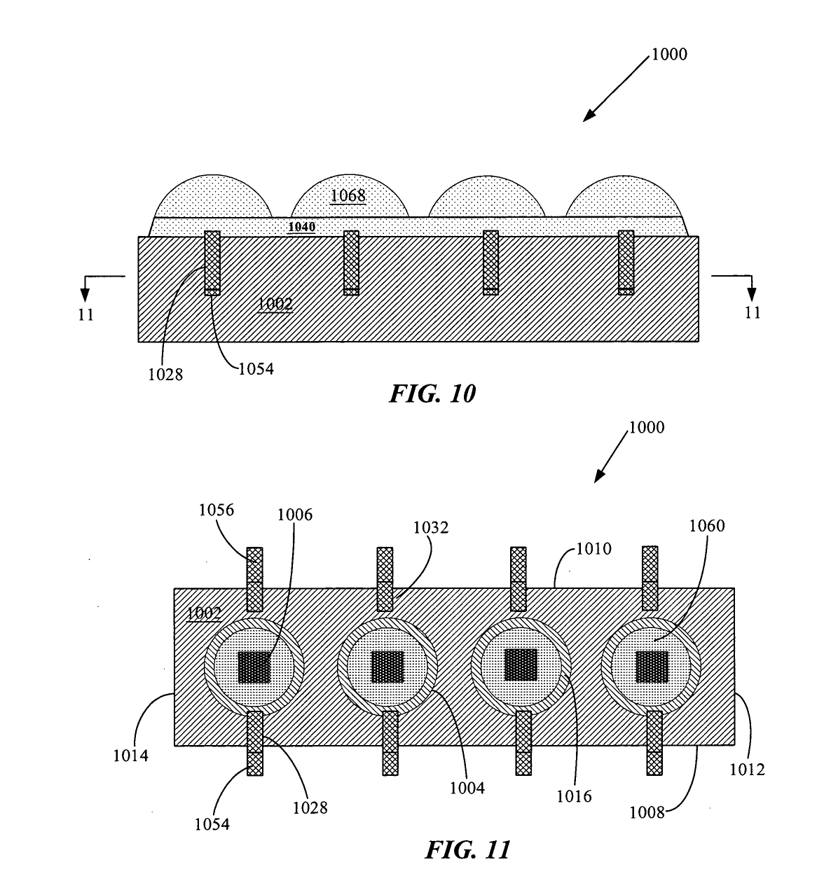

In FIG. 10, a cross-sectional view is shown of an example of a further implementation of a Moisture-Resistant LED Device with Ceramic Substrate 1000. In FIG. 11, a further cross-sectional view is shown, taken on line 11-11 in FIG. 10, of the Moisture-Resistant LED Device with Ceramic Substrate 1000. The Moisture-Resistant LED Device with Ceramic Substrate 1000 may include a ceramic substrate 1002 having a plurality of concave cavities 1004, in each of which an LED 1006 may be placed. As an example, the ceramic substrate 1002 may have lateral sides 1008, 1010, 1012 and 1014. Each concave cavity 1004 may include a light-reflective body 1016 formed of, as an example, an optically-reflective metal or polymeric or metal and polymeric composition. As an example, each concave cavity 1004 of the Moisture-Resistant LED Device with Ceramic Substrate 1000 may include a cathode electrode 1028 and an anode electrode 1032. As a further example, a portion 1054 of each cathode electrode 1028 and a portion 1056 of each anode electrode 1032 may project away from the lateral sides 1008 and 1010, respectively, of the ceramic substrate 1002. A filler body 1060 formed of a material having selected optical transmittance may cover each LED 1006 and fill all or a portion of each concave cavity 1004.

The Moisture-Resistant LED Device with Ceramic Substrate 1000 may, as an example, include a linear array of four concave cavities 1004. It is understood by those of ordinary skill, however, that any selected number of concave cavities 1004 may be included in the Moisture-Resistant LED Device with Ceramic Substrate 1000. It is further understood that such concave cavities 1004 may be arranged in linear and non-linear arrays, blocks, circles, curves and grids, with or without internal and external gaps between adjacent concave cavities 1004, or in any other selected continuous or discontinuous array, provided that the cathode and anode electrodes as arranged are accessible.

The Moisture-Resistant LED Device with Ceramic Substrate 1000 may include a window 1040 formed of a material having selected optical transmittance and a high resistance to moisture absorption. In an example, the ceramic substrate 1002, the window 1040, the cathode electrodes 1028 and the anode electrodes 1032 may together form a sealed package for the LED device 1000. As an example, the sealed package may be hermetically sealed against moisture absorption or intrusion at the temperatures and pressures of typical utilization of LED devices for generating light. As an example, a convex lens 1068 may be provided over and in contact with, or integrally formed with, the window 1040 in alignment with each concave cavity 1004. In another example, a lens having a different shape may be provided over and in contact with, or integrally formed with, the window 1040, such as a unitary convex lens (not shown) in alignment collectively with a plurality of concave cavities 1004. It is understood that LED devices 100, 400 or 700 or more than one of such LED devices 100, 400 and 700 may be incorporated into a Moisture-Resistant LED Device with Ceramic Substrate 1000 in analogous manners.

While the foregoing description refers LED devices having various SMT and through-hole structures, it will be understood that the subject matter is not limited to the structures shown in the figures. Other electrode configurations and other LED device structures including ceramic substrates sealed together with windows are included. LED devices having any selected number and arrangement of concave cavities including LEDs are contemplated, provided that the selected electrodes may be made accessible for interconnection into an external electrical circuit. Although some examples use an LED emitting blue photons to stimulate luminescent emissions from a yellow phosphor in order to produce output light having a white appearance, the subject matter also is not limited to such a device. Any LED device that could benefit from the functionality provided by the components described above may be utilized as a Moisture-Resistant LED Device with Ceramic Substrates as disclosed herein and shown in the drawings.

Moreover, it will be understood that the foregoing description of numerous implementations has been presented for purposes of illustration and description. This description is not exhaustive and does not limit the claimed inventions to the precise forms disclosed. Modifications and variations are possible in light of the above description or may be acquired from practicing the invention. The claims and their equivalents define the scope of the invention.

What is claimed:

1. A New Moisture-Resistant LED Device with Ceramic Substrate, comprising:
a ceramic substrate;
a concave cavity in the ceramic substrate;
a light emitting diode (“LED”) in the concave cavity;
a filler body over the LED; and
a window sealed at an interface with the ceramic substrate.

2. The Moisture-Resistant LED Device with Ceramic Substrate of claim 1, further including surface mount cathode and anode electrode leads for the LED passing through and sealed with the interface.

3. The Moisture-Resistant LED Device with Ceramic Substrate of claim 1, wherein the ceramic substrate has a lateral side, and further including surface mount cathode and anode electrode leads for the LED passing through and sealed with a lateral side.

4. The Moisture-Resistant LED Device with Ceramic Substrate of claim 1, wherein the ceramic substrate has a base, and further including through-hole cathode and anode electrode leads for the LED passing through and sealed with the base.

5. The Moisture-Resistant LED Device with Ceramic Substrate of claim 1, wherein the LED includes a p-doped semiconductor body and an n-doped semiconductor body.

6. The Moisture-Resistant LED Device with Ceramic Substrate of claim 5, including:
a first terminal at a relatively high electrical potential in signal communication with the p-doped semiconductor body; and
a second terminal at a relatively low electrical potential in signal communication with the n-doped semiconductor body.

7. The Moisture-Resistant LED Device with Ceramic Substrate of claim 5, further including a phosphor in the concave cavity.

8. The Moisture-Resistant LED Device with Ceramic Substrate of claim 7, wherein:
the LED has an emission maximum within a range of about 420 nanometers to about 490 nanometers, the n-doped semiconductor body and the p-doped semiconductor body each include a member selected from the group consisting of gallium nitride, indium-gallium-nitride, gallium-aluminum-indium-nitride, and mixtures; and
the phosphor has an emission maximum within a range of about 550 nanometers to about 585 nanometers, the phosphor including a cerium-doped yttrium-aluminum garnet, further including
at least one element selected from the group consisting of yttrium, lutetium, selenium, lanthanum, gadolinium, samarium and terbium,
and at least one element selected from the group consisting of aluminum, gallium and indium.

9. The Moisture-Resistant LED Device with Ceramic Substrate of claim 1, further including a lens.

10. The Moisture-Resistant LED Device with Ceramic Substrate of claim 1, further including a plurality of concave cavities in the ceramic substrate.

11. The Moisture-Resistant LED Device with Ceramic Substrate of claim 1, wherein the ceramic substrate and window are hermetically sealed together.

12. A method of making a Moisture-Resistant LED Device with Ceramic Substrate, comprising:
forming a ceramic substrate having a concave cavity;
placing a light emitting diode (“LED”) in the concave cavity;
forming a filler body over the LED; and
forming and sealing a window at an interface with the ceramic substrate.

13. The method of making a Moisture-Resistant LED Device with Ceramic Substrate of claim 12, further including: forming surface mount cathode and anode electrode leads for the LED passing through and sealed with the interface.

14. The method of making a Moisture-Resistant LED Device with Ceramic Substrate of claim 12, wherein the ceramic substrate has a lateral side, and further including: forming surface mount cathode and anode electrode leads for the LED passing through and sealed with a lateral side.

15. The method of making a Moisture-Resistant LED Device with Ceramic Substrate of claim 12, wherein the ceramic substrate has a base, and further including: forming through-hole cathode and anode electrode leads for the LED passing through and sealed with the base.

16. The method of making a Moisture-Resistant LED Device with Ceramic Substrate of claim 12, wherein placing an LED in the concave cavity further includes: placing an LED including a p-doped semiconductor body and an n-doped semiconductor body.

17. The method of making a Moisture-Resistant LED Device with Ceramic Substrate of claim 16, further including:
forming a first terminal at a relatively high electrical potential in signal communication with the p-doped semiconductor body; and
forming a second terminal at a relatively low electrical potential in signal communication with the n-doped semiconductor body.

18. The method of making a Moisture-Resistant LED Device with Ceramic Substrate of claim 12, further including: forming a lens.

19. The method of making a Moisture-Resistant LED Device with Ceramic Substrate of claim 12, further including: forming a plurality of concave cavities in the ceramic substrate.

20. The method of making a Moisture-Resistant LED Device with Ceramic Substrate of claim 12, further including: hermetically sealing together the ceramic substrate and window.
